(19) United States
(12) Patent Application Publication
(10) Pub. No.: US 2024/0120286 A1
(43) Pub. Date: Apr. 11, 2024

(54) SEMICONDUCTOR PACKAGE

(71) Applicant: Samsung Electronics Co., Ltd., Suwon-si (KR)

(72) Inventors: Hyeonseok LEE, Suwon-si (KR); Eungkyu KIM, Suwon-si (KR); Jongyoun KIM, Suwon-si (KR); Hyeonjeong HWANG, Suwon-si (KR)

(73) Assignee: Samsung Electronics Co., Ltd., Suwon-si (KR)

(21) Appl. No.: 18/371,152

(22) Filed: Sep. 21, 2023

(30) Foreign Application Priority Data
Oct. 7, 2022 (KR) 10-2022-0129037

(51) Int. Cl. H01L 23/544; H01L 23/31; H01L 23/498; H01L 25/10

(52) U.S. Cl. CPC H01L 23/544; H01L 23/3128; H01L 23/49822; H01L 23/49833; H01L 25/105; H01L 24/16; H01L 2223/54426; H01L 2224/16227

(57) ABSTRACT

Provided is a semiconductor package including a lower redistribution structure, an internal semiconductor chip on an upper surface of the lower redistribution structure, an upper redistribution structure electrically connected to the lower redistribution structure through a conductive post, and a molding layer between the upper redistribution structure and the lower redistribution structure, the molding layer being adjacent to the internal semiconductor chip, wherein the upper redistribution structure includes an insulating layer including a redistribution pattern and a first material configured to transmit light, and a fiducial mark formed of the first material, and a lower surface of the fiducial mark is in contact with an upper surface of the molding layer.

### CROSS-REFERENCE TO RELATED APPLICATION

This application claims priority to Korean Patent Application No. 10-2022-0129037, filed on Oct. 7, 2022, in the Korean Intellectual Property Office, the disclosure of which is incorporated by reference herein in its entirety.

### BACKGROUND

Embodiments of the present disclosure relate to a semiconductor package, and more particularly, to a semiconductor package including a semiconductor chip inside a package.

In accordance with the rapid development of the electronics industry and the needs of users, electronic devices are becoming smaller and lighter, and accordingly, high integration of semiconductor chips, which are core components of electronic devices, is required. In addition, as mobile products develop, miniaturization and multifunctionalization are required together. Accordingly, a package on package (PoP) type semiconductor package in which an upper package having a different function is stacked on one lower package has been proposed.

### SUMMARY

One or more embodiments provide a semiconductor package including a fiducial mark for improving the recognition rate of an optical system in a semiconductor package manufacturing process.

According to an aspect of an embodiment, there is provided a semiconductor package including a lower redistribution structure, an internal semiconductor chip on an upper surface of the lower redistribution structure, an upper redistribution structure electrically connected to the lower redistribution structure through a conductive post, and a molding layer between the upper redistribution structure and the lower redistribution structure, the molding layer being adjacent to the internal semiconductor chip, wherein the upper redistribution structure includes an insulating layer including a redistribution pattern and a first material configured to transmit light, and a fiducial mark formed of the first material, and a lower surface of the fiducial mark is in contact with an upper surface of the molding layer.

According to another aspect of an embodiment, there is provided a semiconductor package including a lower redistribution structure, an internal semiconductor chip on an upper surface of the lower redistribution structure, an upper redistribution structure electrically connected to the lower redistribution structure through a conductive post, and a molding layer between the upper redistribution structure and the lower redistribution structure, the molding layer being adjacent to the internal semiconductor chip, wherein the upper redistribution structure includes an insulating layer including a redistribution pattern and a first material configured to transmit light, and a fiducial mark formed of the first material, wherein a lower surface of the fiducial mark is in contact with an upper surface of the molding layer, wherein the upper redistribution structure includes a wiring region and a metal layer region electrically spaced apart from the wiring region, and wherein the fiducial mark is in the metal layer region.

According to another aspect of an embodiment, there is provided a semiconductor package including a lower redistribution structure, an internal semiconductor chip on an upper surface of the lower redistribution structure, an upper redistribution structure electrically connected to the lower redistribution structure through a conductive post, a molding layer between the upper redistribution structure and the lower redistribution structure, the molding layer being adjacent to the internal semiconductor chip, and an upper semiconductor package on an upper surface of the upper redistribution structure, wherein the upper redistribution structure includes an insulating layer including a redistribution pattern and a first material configured to transmit light, and a fiducial mark formed of the first material, wherein a lower surface of the fiducial mark is in contact with an upper surface of the molding layer, wherein the upper redistribution structure includes a wiring region and a metal layer region electrically spaced apart from the wiring region, and wherein the fiducial mark is in a region of the metal layer region that does not include a metal layer.

### BRIEF DESCRIPTION OF DRAWINGS

Embodiments will be more clearly understood from the following detailed description taken in conjunction with the accompanying drawings in which:

FIG. 1 is a plan view illustrating a semiconductor package according to an embodiment;

FIG. 2 is a cross-sectional view of a semiconductor package according to an embodiment of the inventive concept, taken along line A-A′ of FIG. 1;

FIG. 3 is a plan view illustrating a semiconductor package according to an embodiment;

FIG. 4 is a cross-sectional view of a semiconductor package according to an embodiment by cutting a portion B-B′ of FIG. 3;

FIG. 5 is a plan view illustrating a semiconductor package according to an embodiment;

FIG. 6 is a plan view illustrating a semiconductor package according to an embodiment;

FIG. 7 is a plan view illustrating a semiconductor package according to an embodiment;

FIG. 8 is a plan view illustrating a semiconductor package according to an embodiment;

FIG. 9 is a plan view illustrating a semiconductor package according to an embodiment;

FIG. 10 is a plan view illustrating a semiconductor package according to an embodiment;

FIG. 11 is a plan view illustrating a semiconductor package according to an embodiment; and

FIGS. 12A, 12B, 12C, 12D, 12E, and 12F are cross-sectional views illustrating a method of manufacturing a semiconductor package, according to an embodiment.

### DETAILED DESCRIPTION OF EMBODIMENTS

Hereinafter, embodiments will be described in detail with reference to the accompanying drawings. The same reference numerals are used for the same components in the drawings, and duplicate descriptions thereof are omitted. Embodiments described herein are example embodiments, and thus, the disclosure is not limited thereto.

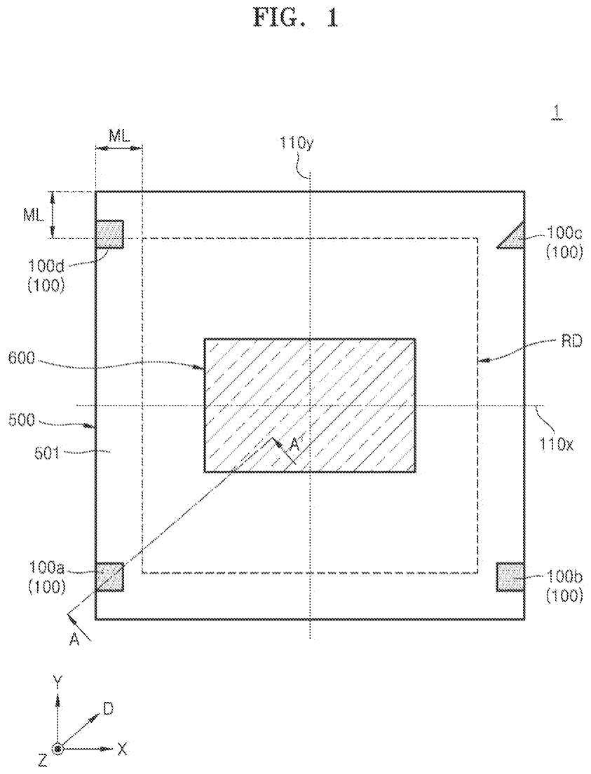

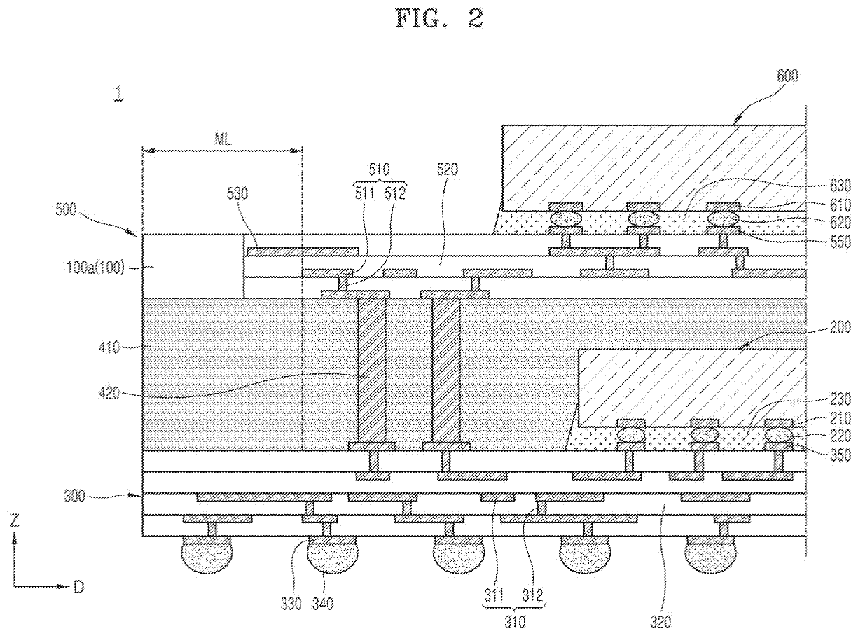

FIG. 1 is a plan view illustrating a semiconductor package 1 according to an embodiment. FIG. 2 is a cross-sectional view of a semiconductor package 1 according to an embodiment, taken along line A-A′ of FIG. 1.

Referring to FIGS. 1 and 2, the semiconductor package 1 may include an internal semiconductor chip 200, a lower redistribution structure 300 on which the internal semiconductor chip 200 is mounted, an upper redistribution structure 500, an upper semiconductor package 600 mounted on the upper redistribution structure 500, a molding layer 410 filled between the lower redistribution structure 300 and the upper redistribution structure 500, and a fiducial mark 100 formed in the upper redistribution structure 500. A direction having both components of the x-axis direction and the y-axis direction of FIG. 1 may be referred to as a first direction D. FIG. 2 is a view appearing on the D-Z axis plane.

The semiconductor package 1 may be a fan out semiconductor package in which a size of the lower redistribution structure 300 is greater than a size of the internal semiconductor chip 200. For example, the horizontal width and horizontal area of the lower redistribution structure 300 may be greater than the horizontal width and horizontal area of the internal semiconductor chip 200. According to another embodiment, the semiconductor package 1 may be a semiconductor package in which a size of the upper redistribution structure 500 is larger than a size of the upper semiconductor package 600. For example, the horizontal width and horizontal area of the upper redistribution structure 500 may be greater than the horizontal width and horizontal area of the upper semiconductor package 600.

The lower redistribution structure 300 may include a lower redistribution pattern 310 and a plurality of lower redistribution insulating layers 320 provided on and covering the lower redistribution pattern 310. The plurality of lower redistribution insulating layers 320 may be mutually stacked in a vertical direction (Z-axis direction). The plurality of lower redistribution insulating layers 320 may be formed of a material film made of an organic compound. For example, each of the plurality of lower redistribution insulating layers 320 may be formed from photo imageable dielectric (PID), Ajinomoto Build-up Film (ABF), or photosensitive polyimide (PSPI).

The lower redistribution pattern 310 may include a plurality of lower redistribution line patterns 311 disposed on at least one of upper and lower surfaces of each of the plurality of lower redistribution insulating layers 320 and a plurality of lower redistribution via patterns 312 extending through at least one of the plurality of lower redistribution insulating layers 320. The plurality of lower redistribution via patterns 312 may electrically connect the plurality of lower redistribution line patterns 311 positioned at different levels in a vertical direction (Z-axis direction). For example, the lower redistribution pattern 310 may be a metal, such as copper (Cu), aluminum (Al), tungsten (W), titanium (Ti), tantalum (Ta), indium (In), molybdenum (Mo), manganese (Mn), cobalt (Co), tin (Sn), Nickel (Ni), magnesium (Mg), rhenium (Re), beryllium (Be), gallium (Ga), ruthenium (Ru), and the like, or an alloy thereof, but is not limited thereto.

Some of the plurality of lower redistribution line patterns 311 may be provided on the upper surface of the lower redistribution structure 300 to constitute a conductive pad 350 connected to a conductive bump 220 attached to the internal semiconductor chip 200 and a conductive pad 350 connected to a conductive post 420. In addition, some of the plurality of lower redistribution line patterns 311 may be provided on the lower surface of the lower redistribution structure 300 to constitute an external connection pad 330 connected to an external connection terminal 340. The external connection terminal 340 may be, for example, a solder ball or a solder bump.

At least some of the plurality of lower redistribution line patterns 311 may be formed integrally with some of the plurality of lower redistribution via patterns 312. For example, some of the plurality of lower redistribution line patterns 311 may be integrally formed with a plurality of lower redistribution via patterns 312 in contact with the lower side of the lower redistribution line patterns 311.

In example embodiments, each lower redistribution via pattern 312 may have a tapered shape in which a horizontal width thereof narrows from an upper side to a lower side thereof. For example, the horizontal width of the plurality of lower redistribution via patterns 312 may gradually narrow as the distance from the upper surface of the lower redistribution structure 300 facing the internal semiconductor chip 200 increases, and in example embodiments, the thickness of the lower redistribution structure 300 along the vertical direction (Z-axis direction) may be between about 30 m and about 100 m. As the lower redistribution structure 300, a redistribution board or a printed circuit board formed using a redistribution process may be used.

The internal semiconductor chip 200 may be disposed on the upper surface of the lower redistribution structure 300. For example, the conductive bumps 220, such as micro bumps, may be connected to conductive pads 210 formed on the lower surface of the internal semiconductor chip 200. The conductive bumps 220 may be respectively connected to the conductive pads 350 positioned on the upper surface of the lower redistribution structure 300 and mounted on the lower redistribution structure 300 in a flip chip method.

In example embodiments, the internal semiconductor chip 200 may be a memory chip. For example, the internal semiconductor chip 200 may include a volatile memory chip and/or a non-volatile memory chip. The volatile memory chip may include, for example, dynamic random access memory (DRAM), high bandwidth memory (HBM) DRAM, static RAM (SRAM), thyristor RAM (TRAM), zero capacitor RAM (ZRAM), or twin transistor RAM (TTRAM). In addition, the non-volatile memory chip may include, for example, a flash memory, magnetic RAM (MRAM), spin-transfer torque MRAM (STT-MRAM), ferroelectric RAM (FRAM), phase change RAM (PRAM), resistive RAM (RRAM), nanotube RRAM, polymer RAM, or an insulator resistance change memory.

In example embodiments, the internal semiconductor chip 200 may be a logic chip. For example, the internal semiconductor chip 200 may be a central processing unit (CPU), a graphics processing unit (GPU), or an application processor (AP).

In example embodiments, the internal semiconductor chip 200 is a communication chip and may include a signal processing circuit for processing a radio signal. For example, the internal semiconductor chip 200 may include a radio-frequency integrated circuit (RFIC).

In FIG. 1, the semiconductor package 1 is illustrated as including one internal semiconductor chip, but is not limited thereto. For example, two or more internal semiconductor chips spaced apart in a horizontal direction (X-axis direction) may be disposed on the lower redistribution structure 300. The two or more internal semiconductor chips may be of the same type or different types.

An underfill layer 230 may be disposed between the lower surface of the internal semiconductor chip 200 and the upper surface of the lower redistribution structure 300. The underfill layer 230 may cover the conductive bumps 220. The underfill layer 230 may be formed of a resin material formed by, for example, a capillary underfill method.

The molding layer 410 may be disposed on the lower redistribution structure 300 to surround at least a portion of the internal semiconductor chip 200. For example, the molding layer 410 may extend along the side of the internal semiconductor chip 200. In example embodiments, the molding layer 410 may include an insulating polymer or an epoxy resin. For example, the molding layer 410 may include an epoxy mold compound (EMC). In example embodiments, an upper surface of the molding layer 410 may be positioned at a higher level than an upper surface of the internal semiconductor chip 200. The molding layer 410 may be positioned between the upper redistribution structure 500 and the lower redistribution structure 300 to be described later, and may surround the conductive post 420 and the internal semiconductor chip 200.

The conductive posts 420 may be horizontally spaced apart from sidewalls of the internal semiconductor chip 200. The conductive posts 420 may be through mold vias that pass through the molding layer 410 in a vertical direction (Z-axis direction). The conductive post 420 may be formed of, for example, copper (Cu).

The conductive post 420 may be a vertical connection conductor for electrically connecting the lower redistribution pattern 310 of the lower redistribution structure 300 and an upper redistribution pattern 510 of the upper redistribution structure 500 to each other. The lower end of the conductive post 420 may be connected to at least a portion of the lower redistribution pattern 310 provided on the upper surface of the lower redistribution structure 300, and the upper end of the conductive post 420 may be connected to a portion of the lower redistribution pattern 510 provided on a lower surface of the upper redistribution structure 500. A level of the upper end of the conductive post 420 in the vertical direction (Z-axis direction) may be equal to or higher than that of the upper surface of the internal semiconductor chip 200.

The upper redistribution structure 500 may include an upper redistribution pattern 510 and a plurality of upper redistribution insulating layers 520 provided on and covering the upper redistribution pattern 510.

The upper redistribution structure 500 may be formed to cover the upper surface of the molding layer 410. The horizontal width and horizontal area of the upper redistribution structure 500 may be greater than the horizontal width and horizontal area of the internal semiconductor chip 200. In example embodiments, a size of the upper redistribution structure 500 may be the same as a size of the lower redistribution structure 300. The size of the upper redistribution structure 500 and the size of the lower redistribution structure 300 may be the same as the size of the semiconductor package 1.

The plurality of upper redistribution insulating layers 520 may be mutually stacked in a vertical direction (Z-axis direction). The plurality of upper redistribution insulating layers 520 may be formed of a material film made of an organic compound. The plurality of upper redistribution insulating layers 520 may be made of a first material that transmits light. The first material may include an organic material. For example, the plurality of upper redistribution insulating layers 520 made of the first material may be PID layers. Hereinafter, light in the present disclosure is described as an example of visible light, but may be infrared rays or ultraviolet rays, and embodiments are not limited thereto.

The upper redistribution pattern 510 may include a plurality of upper redistribution line patterns 511 disposed on at least one of upper and lower surfaces of each of the plurality of upper redistribution insulating layers 520 and a plurality of upper redistribution via patterns 512 extending through at least one of the plurality of upper redistribution insulating layers 520. The plurality of upper redistribution via patterns 512 may electrically connect upper redistribution line patterns 511 positioned at different levels in a vertical direction (Z-axis direction). For example, the upper redistribution pattern 510 may be a metal, such as copper (Cu), aluminum (Al), tungsten (W), titanium (Ti), tantalum (Ta), indium (In), molybdenum (Mo), manganese (Mn), cobalt (Co), tin (Sn), Nickel (Ni), magnesium (Mg), rhenium (Re), beryllium (Be), gallium (Ga), ruthenium (Ru), and the like, or an alloy thereof, but is not limited thereto.

Some of the plurality of upper redistribution line patterns 511 may be provided on the lower surface of the upper redistribution structure 500 to constitute a connection pad connected to the upper end of the conductive post 420.

At least some of the plurality of upper redistribution line patterns 511 may be formed integrally with some of the plurality of upper redistribution via patterns 512. For example, some of the plurality of upper redistribution line patterns 511 may be integrally formed with the upper redistribution via pattern 512 contacting the lower side of the upper redistribution line patterns 511.

In example embodiments, each upper redistribution via pattern 512 may have a tapered shape extending with a horizontal width narrowing in a direction from an upper side of the upper redistribution via pattern 512 to a lower side thereof. For example, the horizontal width of the plurality of upper redistribution via patterns 512 may gradually narrow toward the lower surface of the upper redistribution structure 500 facing the upper surface of the internal semiconductor chip 200.

In example embodiments, the thickness of the upper redistribution structure 500 in the vertical direction (Z-axis direction) may be between about 10 μm and about 100 μm.

The upper redistribution structure 500 may include a fiducial mark 100 observable from the upper surface of the upper redistribution structure 500. The upper surface of the upper redistribution structure 500 may be divided into a wiring region RD where the upper redistribution pattern 510 is formed and a metal layer region ML where the upper redistribution pattern 510 is not formed.

The wiring region RD is a region in which an upper redistribution pattern 510 for electrical signal transmission is formed in the upper redistribution structure 500. For example, as shown in FIG. 1, the wiring region RD may have a rectangular shape similar to the circumference of the semiconductor package 1. However, since the wiring region RD may be changed according to the design of the upper redistribution pattern 510, the shape of the wiring region RD is not limited thereto.

The metal layer region ML may be divided into a portion where a metal layer is formed and a portion where a metal layer is not formed. The fiducial mark 100 may be formed in the metal layer region ML. A dummy wiring formed in the same way as the redistribution pattern may be formed in the metal layer region ML.

As described above, the plurality of upper redistribution insulating layers 520 may be made of a material that transmits at least a portion of light. The plurality of upper redistribution insulating layers 520 may be composed of organic layers that transmit at least a portion of light. The plurality of upper redistribution insulating layers 520 may be formed as PID layers.

The fiducial mark 100 is formed in the metal layer region ML, and may also be formed on the upper redistribution structure 500 on which a metal layer 530 is not formed. Accordingly, the fiducial mark 100 is composed of only the upper redistribution insulating layer 520 in the upper redistribution structure 500. Since the upper redistribution insulating layer 520 may transmit at least some light, when observing the fiducial mark 100 formed only of the upper redistribution insulating layer 520 externally, the upper surface of the molding layer 410 formed on the lower surface of the upper redistribution structure 500 may be observed through the transmitted light. The lower surface of the upper redistribution insulating layer 520 constituting the fiducial mark 100 is configured to come into contact with the upper surface of the molding layer 410.

Since the molding layer 410 hardly transmits light, when observed externally, the molding layer 410 may be observed as the fiducial mark 100. For example, the molding layer 410 may be observed as a relatively dark color. The metal layer 530 and the upper redistribution pattern 510 formed on the boundary of the fiducial mark 100 may be observed in a relatively bright color compared to the fiducial mark 100 due to the characteristics of the metal. According to an embodiment, the fiducial mark 100 may be observed in a relatively dark color close to black, and the metal layer 530 including Cu and the upper redistribution pattern 510 may be observed in a characteristic color of Cu. Therefore, when observing the semiconductor package 1 according to an embodiment, externally, the fiducial mark 100 formed on the upper redistribution structure 500 may be more clearly observed in contrast with the metal layer 530 formed around the upper redistribution structure 500 in color or brightness. Various shapes of the fiducial mark 100, which will be described later, may be determined according to the design of the metal layer 530 or the upper redistribution pattern 510, and the shape of the fiducial mark 100 is not limited due to the drawings herein.

When the fiducial mark 100 is more clearly observed, the recognition rate of the fiducial mark 100 in an optical or illumination system may be improved in the process. When the alignment of the semiconductor package 1 or the recognition rate of an optical or illumination system for the next process is improved, the manufacturing process of the semiconductor package 1 may be performed more smoothly. For example, alignment in a direction or position may be required in a semiconductor package manufacturing process to be described later. An optical system or an illumination system may recognize the fiducial mark 100 and determine the direction of the semiconductor package 1. The direction of the semiconductor package 1 may be adjusted through a separate device.

As described later, a manufacturing method of the semiconductor package 1, according to an embodiment, may be similar to a related semiconductor package manufacturing process, but the manufacturing method is possible through the design of the metal layer and redistribution pattern of the upper redistribution structure. Therefore, since the fiducial mark 100 according to an embodiment may be applied by changing the design of the metal layer and the redistribution pattern, the existing semiconductor manufacturing equipment may be used as is.

Hereinafter, in the present disclosure, the fiducial mark 100 is referred to separately based on a first axis 110x and a second axis 110y, as described later. A fiducial mark on the lower side with respect to the first axis 110x and on the left side with respect to the second axis 110y is referred to as a first fiducial mark 100a, a fiducial mark on the lower side with respect to the first axis 110x and on the right side with respect to the second axis 110y is referred to as a second fiducial mark 100b, a fiducial mark on the upper side with respect to the first axis 110x and on the right side with respect to the second axis 110y is referred to as a third fiducial mark 100c, and a fiducial mark on the upper side with respect to the first axis 110x and on the left side with respect to the second axis 110y is referred to as a fourth fiducial mark 100d.

To align a semiconductor package, it is necessary to recognize the direction in which the semiconductor package is placed through an illumination system or an optical system. Therefore, the fiducial mark 100 included in the semiconductor package 1, which is an embodiment, needs to be formed so that an illumination system or an optical system may recognize the direction in which the semiconductor package 1 in which the fiducial mark 100 is formed is placed. As in FIG. 1, in the semiconductor package 1 in which four fiducial marks are formed, even if the positions of all four fiducial marks 100 are substantially symmetrical, the shape of one fiducial mark 100 may be formed to be different. According to an embodiment, the third fiducial mark 100c may have a triangular shape. The remaining three fiducial marks 100a, 100b, and 100c may have a rectangular shape. An optical system or an illumination system may recognize the direction in which the semiconductor package 1 is placed through the triangular fiducial mark, that is, the third fiducial mark 100c.

For example, if the semiconductor package 1 in FIG. 1 is placed in a clockwise rotation state of 90°, the third fiducial mark 100c may be positioned at the bottom left in the drawing. The illumination system or the optical system may recognize the position of the third fiducial mark 100c having a different shape from the fiducial marks 100a, 100b, and 100d, determine whether the semiconductor package 1 is rotated, and determine the degree of rotation. The semiconductor package 1 may be adjusted through a separate device so that the third fiducial mark 100c is positioned at the upper right corner. Therefore, when the upper semiconductor package 600 is mounted on the upper redistribution structure 500, the fiducial mark recognition rate of the optical system may be improved.

According to an embodiment, when the semiconductor package 1 has a rectangular shape, first and second axes 110x and 110y parallel to the width or length of the semiconductor package 1, passing through the center of the semiconductor package 1, and orthogonal to each other may be considered. The first axis 110x may be parallel to the width of the upper redistribution structure 500 in the drawing. The second axis 110y may be parallel to the vertical direction of the upper redistribution structure 500 in the drawing. For example, the first axis 110x may be parallel to the x-axis, and the second axis 110y may be parallel to the y-axis.

As described above, the direction in which a semiconductor package is placed may need to be recognized through an illumination system or an optical system. Therefore, the fiducial mark 100 included in the semiconductor package 1, which is an embodiment, is required to be formed so that an illumination system or an optical system may recognize the direction in which the semiconductor package 1 in which the fiducial mark 100 is formed is placed.

As in FIG. 1, the first fiducial mark 100a is symmetrical to the second fiducial mark 100b with respect to the second axis 110y. Also, the fiducial mark 100a is symmetrical to the fourth fiducial mark 100d with respect to the first axis 110x. However, since the shape of the third fiducial mark 100c is different from that of the other fiducial marks (the first, second, and fourth fiducial marks 100a, 100b, and 100d), the third fiducial mark 100c is not symmetrical with other fiducial marks with respect to the first axis 110x and the second axis 110y. Therefore, the rotation degree of the semiconductor package 1 according to an embodiment may be determined according to the position of the fiducial mark 100.

When the width of the fiducial mark 100 is relatively large, the recognition rate of an optical system or an illumination system may increase, but the design of the upper redistribution structure 500 may be limited. When the width of the fiducial mark 100 is relatively small, the recognition rate of the optical system or illumination system may decrease. Accordingly, the width of the fiducial mark 100 may be set according to the width of the semiconductor package. For example, when the semiconductor package 1 and the upper redistribution structure 500 have a rectangular shape, the horizontal and vertical widths of the fiducial mark 100 may be less than 1/10 of the horizontal or vertical width of the semiconductor package 1 or the horizontal or vertical width of the upper redistribution structure 500.

The signal between the external device external to the semiconductor package 1 and the upper semiconductor package 600 may be transmitted through an electrical path via the external connection terminal 340, the lower redistribution pattern 310 of the lower redistribution structure 300, the conductive post 420, and the upper redistribution pattern 510 of the upper redistribution structure 500. According to another embodiment, a signal between an external device outside the semiconductor package 1 and the internal semiconductor chip 200 may be transmitted through an electrical path via the external connection terminal 340, the lower redistribution pattern 310 of the lower redistribution structure 300, and the conductive bump 220.

For example, a power/ground signal or an input/output data signal may be transmitted between an external device and individual elements of the upper semiconductor package 600 through an electrical path via the external connection terminal 340, the lower redistribution pattern 310 of the lower redistribution structure 300, the conductive post 420, and the upper redistribution pattern 510 of the upper redistribution structure 500. According to another embodiment, power/ground signals or input/output data signals may be transmitted between an external device and individual elements of the internal semiconductor chip 200 through an electrical path via the external connection terminal 340, the lower redistribution pattern 310 of the lower redistribution structure 300, and the conductive bump 220.

The upper semiconductor package 600 may be disposed on the upper surface of the upper redistribution structure 500. For example, a conductive pad 610 formed on a lower surface of the upper semiconductor package 600 may be connected to a conductive bump 620, such as a micro bump. Also, the upper semiconductor package 600 may be mounted on the upper redistribution structure 500 by connecting the conductive pad 550 to the conductive bump 620 located on the upper surface of the upper redistribution structure 500.

In example embodiments, the upper semiconductor package 600 may include a memory chip. For example, the upper semiconductor package 600 may include a volatile memory chip and/or a non-volatile memory chip. The volatile memory chip may include, for example, DRAMHBM DRAM, SRAM, TRAM, ZRAM, or TTRAM. In addition, the nonvolatile memory chip may include, for example, a flash memory, MRAM, STT-MRAM, FRAM, PRAM, RRAM, nanotube RRAM, polymer RAM, or an insulator resistance change memory.

In example embodiments, the upper semiconductor package 600 may include a logic chip. For example, the upper semiconductor package 600 may include a CPU, a GPU, or an AP.

In example embodiments, the upper semiconductor package 600 is a communication chip and may include a signal processing circuit for processing a radio signal. For example, the upper semiconductor package 600 may include an RFIC.

In FIG. 1, the semiconductor package 1 is illustrated as including one upper semiconductor package, but embodiments are not limited thereto. For example, two or more semiconductor packages spaced apart in a horizontal direction may be disposed on the upper redistribution structure 500. The two or more semiconductor packages may be of the same type or different types.

An underfill layer 630 may be arranged between the lower surface of the upper semiconductor package 600 and the upper surface of the upper redistribution structure 500. The underfill layer 630 may be provided on and cover the conductive bumps 620. The underfill layer 630 may be formed of a resin material formed by, for example, a capillary underfill method.

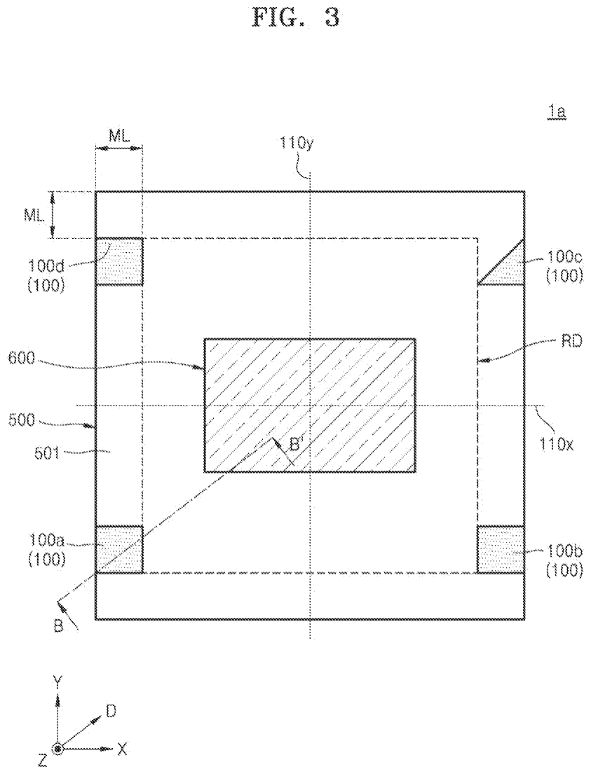

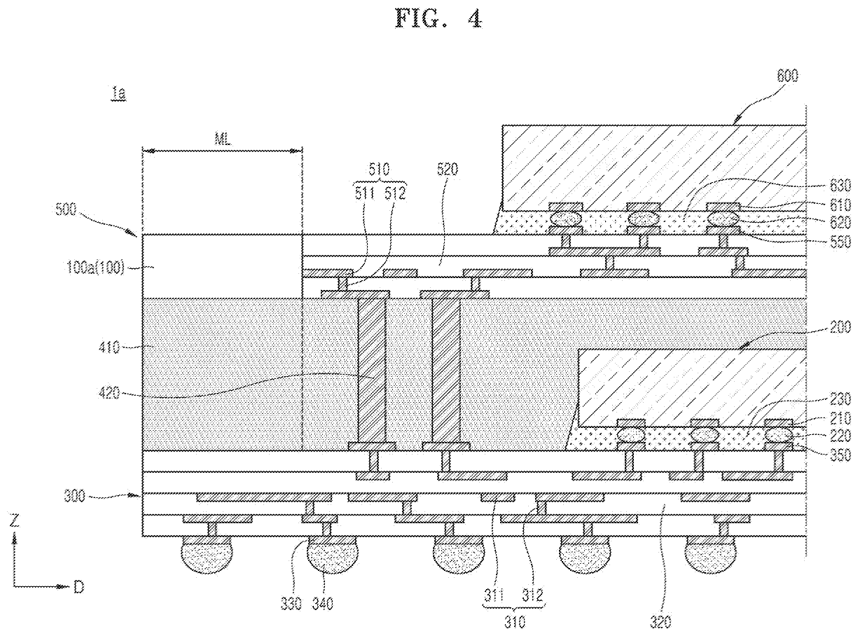

FIG. 3 is a plan view illustrating a semiconductor package 1a according to an embodiment. FIG. 4 is a cross-sectional view of a semiconductor package 1a according to an embodiment, taken along line B-B′ of FIG. 3. Repeated descriptions as those given above are omitted. A direction having both components of the x-axis direction and the y-axis direction of FIG. 1 may be referred to as a first direction D. FIG. 4 is a view appearing on the D-Z axis plane.

Referring to FIGS. 3 and 4, the fiducial mark 100 may be formed in the metal layer region ML, and the fiducial mark 100 may be formed to reach the outer edge of the wiring region RD. Unlike the case of FIGS. 1 and 2, the width of the fiducial mark 100 may be substantially equal to the width of the metal layer region ML. Accordingly, the width of the fiducial mark 100 of FIGS. 3 and 4 may be greater than that of the fiducial mark 100 of FIGS. 1 and 2. For example, the fiducial mark 100 may be formed directly adjacent to the upper redistribution line pattern 511.

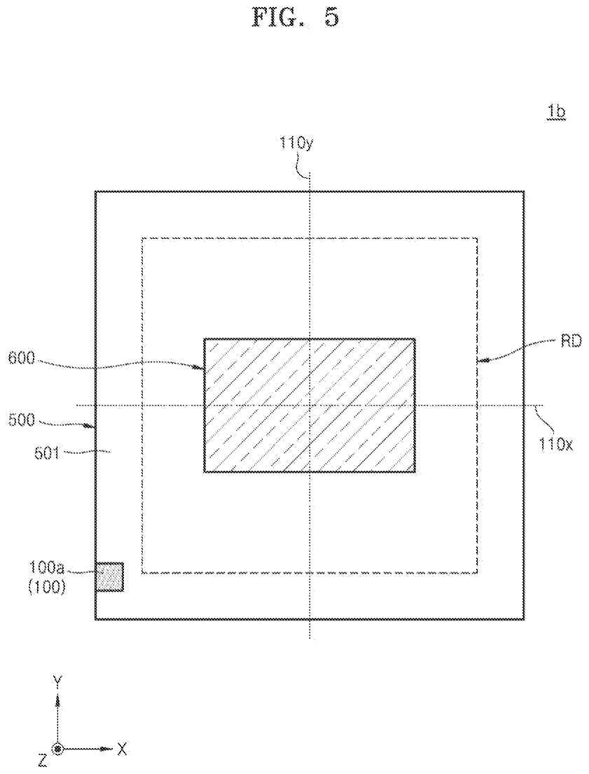

FIG. 5 is a plan view illustrating a semiconductor package 1b according to an embodiment.

Referring to FIG. 5, one fiducial mark 100 may be formed in the upper redistribution structure 500. For example, as shown in FIG. 5, a first fiducial mark 100a having a rectangular shape may be formed to be positioned at a lower left portion of the drawing. When one fiducial mark 100 is formed, since no other fiducial mark is formed, the first fiducial mark 100a may not form symmetry with respect to the first axis 110x and the second axis 110y. Accordingly, it is possible to determine the degree to which the semiconductor package 1b is rotated based on the position of the fiducial mark 100. The rotation degree of the semiconductor package 1b may be determined, and the semiconductor package 1b may be aligned to a desired position using a separate device.

For example, when the semiconductor package 1b is rotated and the first fiducial mark 100a is located in the lower right corner, the optical system or the illumination system may determine that the semiconductor package 1b is rotated by 90 degrees counterclockwise relative to the direction to be aligned.

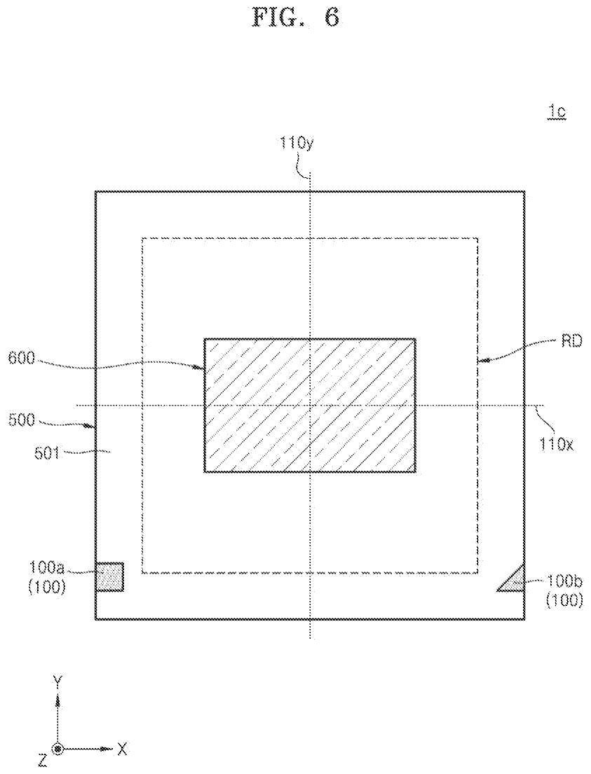

FIG. 6 is a plan view illustrating a semiconductor package 1c according to an embodiment. Referring to FIG. 6, two fiducial marks 100 may be formed. The two fiducial marks 100 may have the same shape or different shapes. In the case of two fiducial marks 100 having the same shape, it is possible to determine whether the semiconductor package 1c is rotated through a position where the two fiducial marks 100 are placed. In addition, the degree of rotation may be determined through the fiducial mark 100 and the semiconductor package 1c may be aligned through a separate device.

The fiducial marks 100 may have different shapes. For example, as shown in FIG. 6, a first fiducial mark 100a having a rectangular shape may be formed at a lower left corner and a second fiducial mark 100b having a triangular shape may be formed at a lower right corner. Since the first fiducial mark 100a and the second fiducial mark 100b are formed asymmetrically with respect to the first axis 110x and the second axis 110y, an optical system or an illumination system may determine may determine whether the semiconductor package 1d is rotated through the fiducial mark 100.

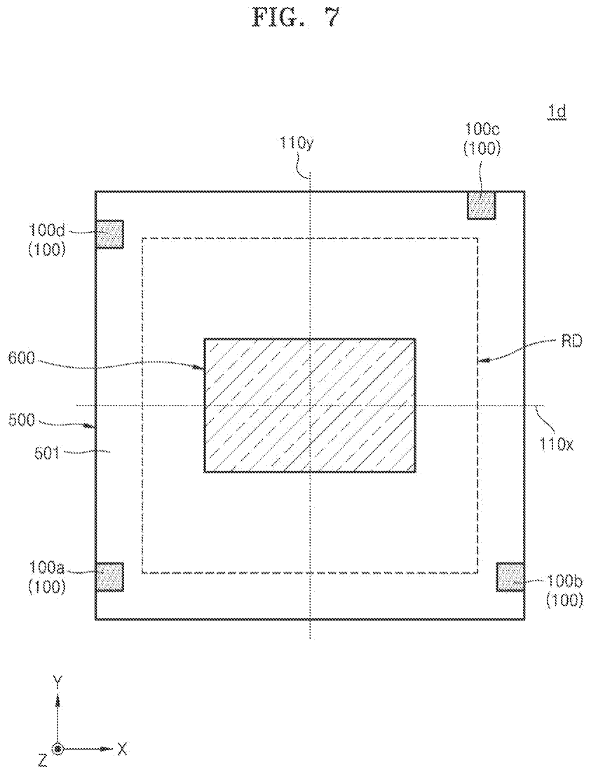

FIG. 7 is a plan view illustrating a semiconductor package 1d according to an embodiment. Referring to FIG. 7, four fiducial marks 100 may be formed, and all of the fiducial marks 100a, 100b, 100c, and 100d may have the same shape. For example, the fiducial marks 100a, 100b, 100c, and 100d may have a square shape as shown in FIG. 7. Unlike FIG. 7, when the positions of the fiducial marks 100 are formed at symmetrical positions with respect to the first axis 110x and the second axis 110y, it is difficult to determine whether the semiconductor package is rotated through an optical system or an illumination system. Also, it is difficult to determine the degree to which the semiconductor package is rotated.

As in FIG. 7, as the position of the third fiducial mark 100c is not symmetrical, if at least some of the fiducial marks 100a, 100b, 100c, and 100d are not symmetrical with respect to the first axis 110x or the second axis 110y, an optical system or an illumination system may determine whether the semiconductor package 1d is rotated. In addition, the degree to which the semiconductor package 1d is rotated may also be determined.

For example, as shown in FIG. 7, the square-shaped fiducial mark (the third fiducial mark 100c) may be formed at the upper right corner so as not to be symmetrical with respect to the first axis 110x or the second axis 110y with other fiducial marks. The optical system or the illumination system may determine whether the semiconductor package 1d is rotated through the position of the third fiducial mark 100c. In addition, the degree to which the semiconductor package 1d is rotated may also be determined.

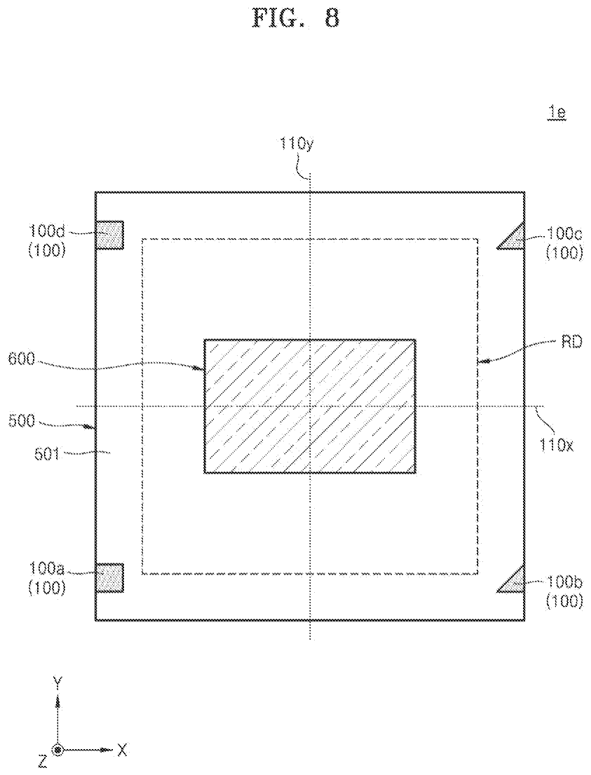

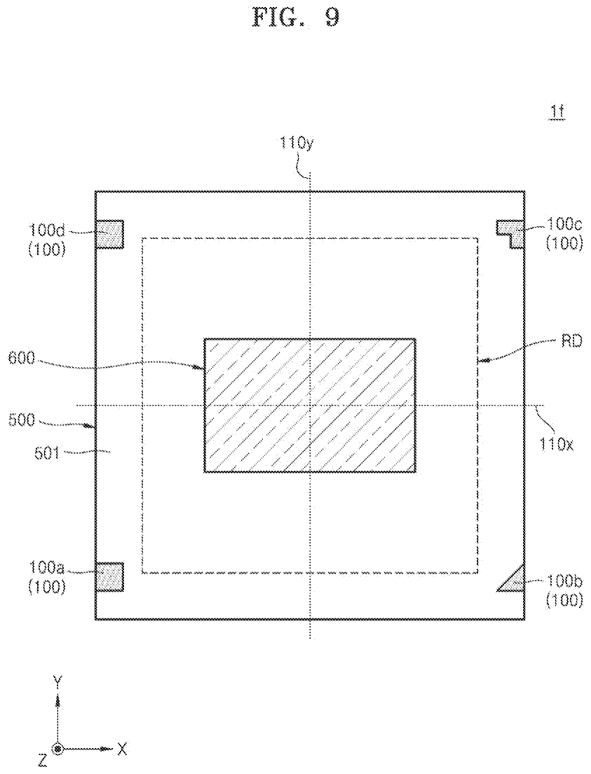

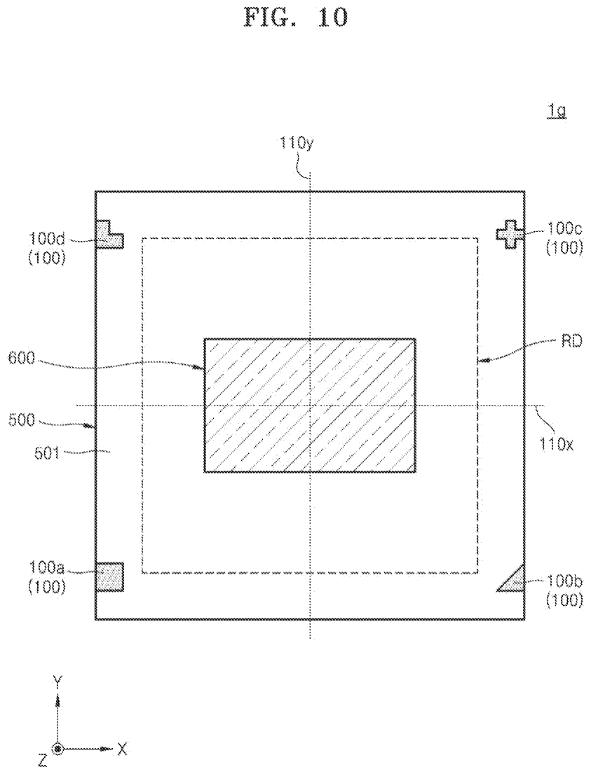

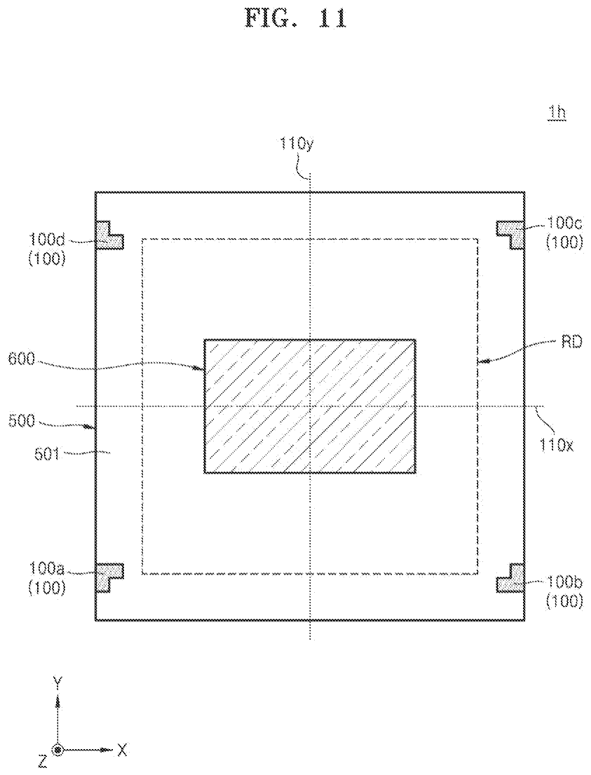

FIG. 8 is a plan view illustrating a semiconductor package be according to an embodiment. FIG. 9 is a plan view illustrating a semiconductor package if according to an embodiment. FIG. 10 is a plan view illustrating a semiconductor package 1g according to an embodiment. FIG. 11 is a plan view illustrating a semiconductor package 1h according to an embodiment.

Referring to FIG. 8, two of the four fiducial marks 100 of the semiconductor package 1e may have two identical shapes. Based on the first axis 110x, the first fiducial mark 100a is symmetrical with the fourth fiducial mark 100d. Based on the first axis 110x, the second fiducial mark 100b is symmetrical with the third fiducial mark 100c. However, based on the second axis 110y, the shape of the fiducial mark is different so that the first fiducial mark 100a and the fourth fiducial mark 100d are not symmetrical with the second fiducial mark 100b and the third fiducial mark 100c, respectively. Accordingly, the optical system or the illumination system may determine whether the semiconductor package 1e is rotated through the position of the fiducial mark 100. In addition, the degree to which the semiconductor package 1e is rotated may also be determined.

Referring to FIG. 9, the four fiducial marks 100 of the semiconductor package if may have three types of shapes. For example, the first fiducial mark 100a and the fourth fiducial mark 100d may have the same shape. For example, as shown in FIG. 9, the first fiducial mark 100a and the fourth fiducial mark 100d have the same square shape, and may have a shape different from that of the second fiducial mark 100b and the third fiducial mark 100c. For example, the second fiducial mark 100b may have a triangular shape and the third fiducial mark 100c may have an ‘L’ shape.

Referring to FIG. 10, four fiducial marks 100 of the semiconductor package 1g may be configured in four types of shapes. For example, all four fiducial marks 100 may have different shapes. For example, the fiducial mark 100 may include a first fiducial mark 100a having a square shape, a second fiducial mark 100b having a triangular shape, a third fiducial mark 100c having a cross shape, and a fourth fiducial mark 100d having an ‘L’ shape.

Referring to FIG. 11, all four fiducial marks 100 of the semiconductor package 1h have the same shape, but the shapes of the fiducial marks may have different directions. If the fiducial mark 100 is in the shape of an ‘L’ and a triangle, the direction of each shape of the fiducial mark 100 may be distinguished. Therefore, even if the position of the fiducial mark 100 is symmetrical with respect to the first axis 110x and the second axis 110y, whether or not the semiconductor package 1h is rotated may be determined through the direction of the shape of the fiducial mark 100.

In the case of a shape in which a protrusion angle formed by the corners forming the shape of the fiducial mark 100 meet each other, depending on the position of the protrusion angle, it may be determined whether the shape of the fiducial mark 100 is rotated. For example, shapes with protrusion angles include ‘L’ shapes and right triangles.

A shape in which a cross-shaped fiducial mark and a square-shaped fiducial mark are rotated by 90° or 180° is indistinguishable from a non-rotated shape of a cross-shaped fiducial mark and a square-shaped fiducial mark.

A shape in which the fiducial mark in the right triangle shape and the fiducial mark in the ‘L’ shape are rotated by 90° or 180° is distinguished from a non-rotated shape of a right triangle-shaped fiducial mark and an ‘L’-shaped fiducial mark. The right triangle fiducial mark and the ‘L’ shaped fiducial mark have an asymmetric protrusion angle formed by the meeting of the corners constituting each shape.

Accordingly, it is possible to determine whether or not the semiconductor package 1h has rotated and the degree of rotation through the fiducial marks 100 having the same shape and having protrusion angles directed in different directions. However, the shape of the fiducial mark 100 is not limited thereto.

For example, all of the fiducial marks 100 of the semiconductor package 1h are ‘L’-shaped fiducial marks, but all four fiducial marks 100 may have different directions in which protrusion angles are directed. Based on the first axis 110x, the first fiducial mark 100a and the fourth fiducial mark 100d may be symmetrical to each other. Based on the first axis 110x, the second fiducial mark 100b and the fourth fiducial mark 100d may be symmetrical to each other. However, based on the second axis 110y, the first fiducial mark 100a and the second fiducial mark 100b have the same shape but are not symmetrical to each other. Similarly, based on the second axis 110y, the fourth fiducial mark 100d and the third fiducial mark 100c have the same shape but different directions and are not symmetrical with each other. Therefore, although all of semiconductor packages 1h are composed of fiducial marks 100 having the same shape, it is possible to determine whether or not a semiconductor package 1h is rotated due to the direction of each shape of the fiducial marks 100 and the degree of rotation.

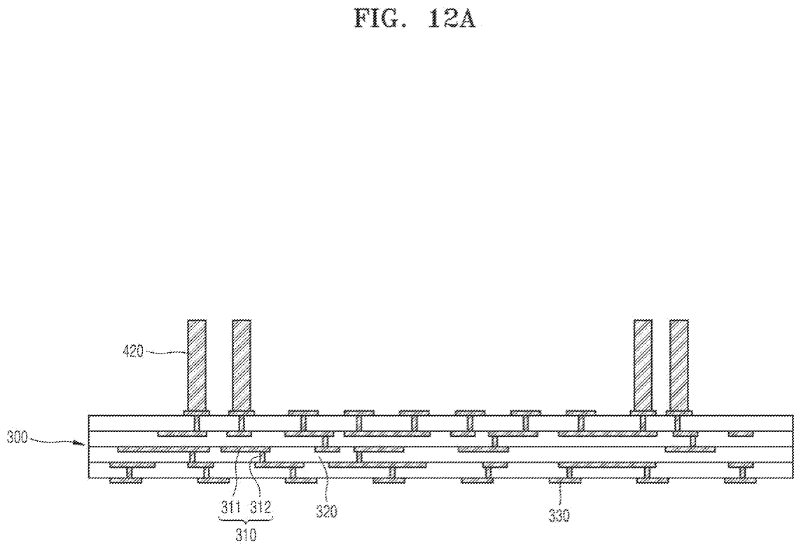

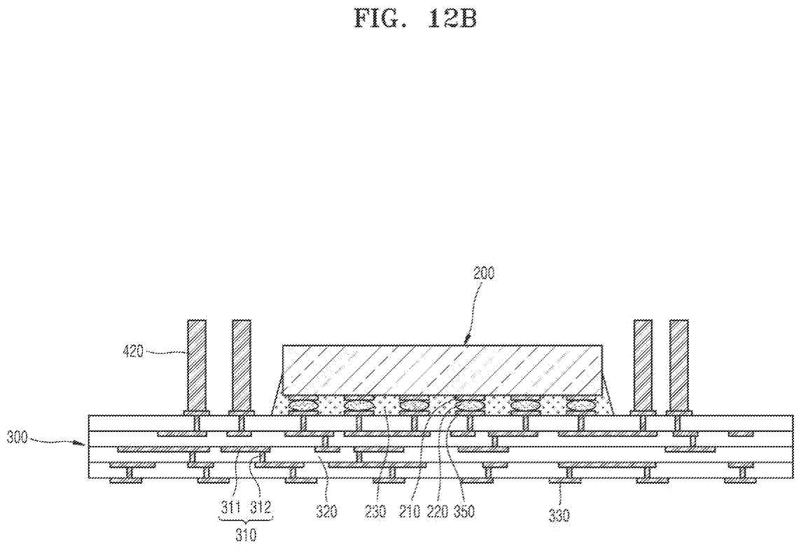

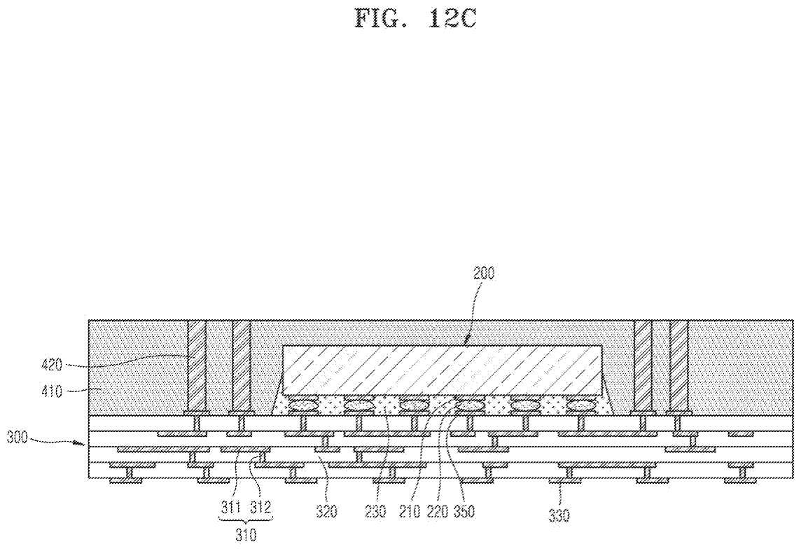

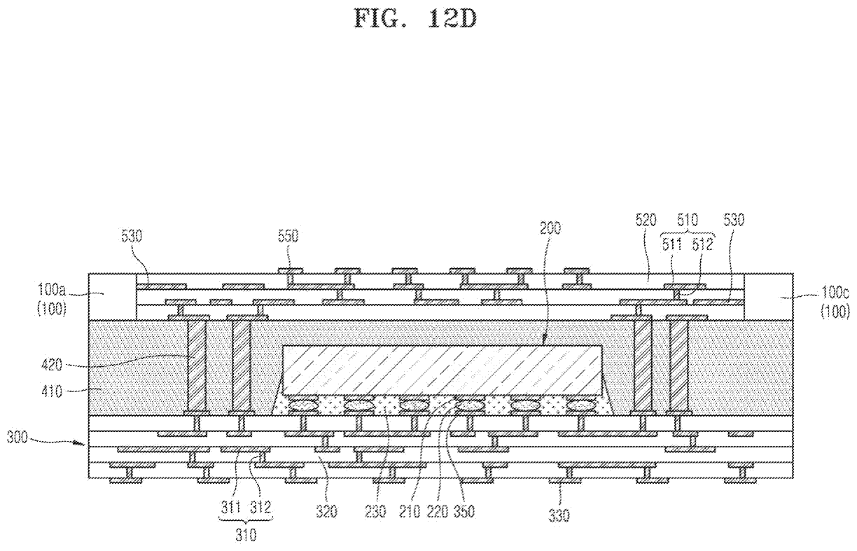

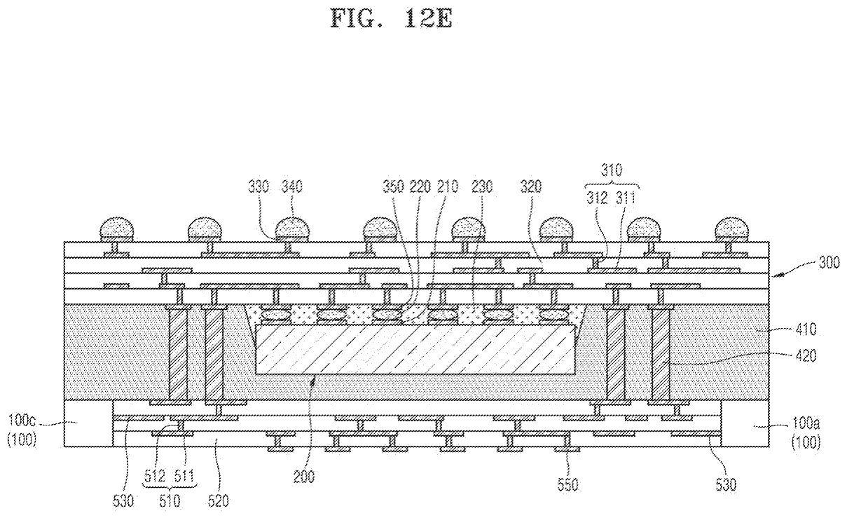

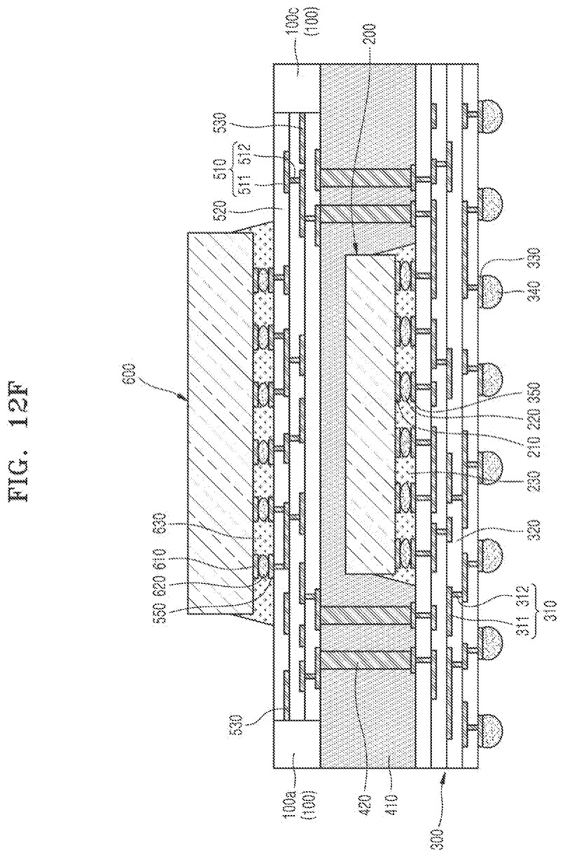

FIGS. 12A to 12F are cross-sectional views illustrating a method of manufacturing a semiconductor package 1, according to an embodiment. Hereinafter, a manufacturing method for the semiconductor package 1 illustrated in FIG. 1 is described with reference to FIGS. 12A to 12F.

FIGS. 12A to 12F are diagrams illustrating a manufacturing method of the semiconductor package 1 based on a cross-section cut by a plane passing through the first fiducial mark 100a and the third fiducial mark 100c of the semiconductor package 1, which is an embodiment.

Referring to FIG. 12A, a lower redistribution structure 300 is formed on a carrier substrate. The carrier substrate may include a second adhesive material layer such as a release film on one surface thereof. The lower redistribution structure 300 may include a plurality of lower redistribution insulating layers 320 sequentially stacked on the carrier substrate, and a lower redistribution pattern 310 insulated by the plurality of lower redistribution insulating layers 320. To form the lower redistribution structure 300, a first operation of forming a conductive material film on a carrier substrate and patterning the conductive material film to form a lower redistribution line pattern 311 of a first layer, a second operation of forming a lower redistribution insulating layer 320 covering the lower redistribution line pattern 311 of the first layer and having a via hole, and a third operation of forming a lower redistribution via pattern 312 filling the via hole of the lower redistribution insulating layer 320 and a lower redistribution line pattern 311 extending along the upper surface of the lower redistribution insulating layer 320 are performed, and then the second and third operations may be repeated several times. A conductive pad 350 to be connected to the conductive post 420 and the conductive bump 220 to be described later may be patterned and formed. The conductive posts 420 may be formed on conductive pads 350 located on the lower redistribution structure 300.

Referring to FIG. 12B, the conductive pad 210 located on the lower surface of the internal semiconductor chip 200 and the conductive pad 350 formed on the upper surface of the lower redistribution structure 300 are electrically connected to each other through the conductive bump 220. The internal semiconductor chip 200 may be mounted on the upper surface of the lower redistribution structure 300. For example, a conductive bump 220 such as a micro bump may be positioned on a lower surface of the internal semiconductor chip 200 and mounted on the lower redistribution structure 300 in a flip chip method.

The underfill layer 230 may be formed to surround the conductive bumps 220 between the lower surface of the internal semiconductor chip 200 and the upper surface of the lower redistribution structure 300. For example, the underfill layer 230 may be formed of a resin material formed by a capillary underfill method.

Referring to FIG. 12C, a molding layer 410 may be formed to surround semiconductor devices placed on the lower redistribution structure 300. A molding layer 410 may be formed on the lower redistribution structure 300 to cover the internal semiconductor chip 200 and the conductive post 420. For example, the molding layer 410 may be formed through a molded underfill process.

Thereafter, a polishing process is performed on the resulting product on which the molding layer 410 is formed so that the conductive posts 420 are exposed. A portion of the molding layer 410 and a portion of the conductive posts 420 may be removed by the polishing process. As a result of the polishing process, the upper surface of the molding layer 410 and the surface of the conductive posts 420 may be exposed. According to another embodiment, polishing may be performed such that the upper surface of the internal semiconductor chip 200 is exposed. A surface of the molding layer 410 and an exposed section of the conductive posts 420 may be on the same plane. For example, the polishing process may include a grinding process using a diamond wheel, etch-back, chemical mechanical polishing, and the like.

Referring to FIG. 12D, an upper redistribution structure 500 may be placed on the result of FIG. 12C. The upper redistribution structure 500 may be formed through the same process as the lower redistribution structure 300. However, to form the fiducial mark 100 in the upper redistribution structure 500, a metal layer may be formed in the metal layer region ML, not in the wiring region RD, except for a portion where the fiducial mark 100 is to be formed. When forming the upper redistribution structure 500, a plurality of upper redistribution insulating layers 520 are stacked. When stacking each upper redistribution insulating layer 520, by forming a conductive material film and patterning the conductive material film, an upper redistribution pattern 510 and a metal layer are formed, and the conductive material film is removed where the fiducial mark 100 is to be located. The fiducial mark 100 may be more easily formed by changing the design of the upper redistribution pattern 510 of the upper redistribution structure 500 and the metal layer without changing the existing process.

Referring to FIG. 12E, the carrier substrate supporting the lower redistribution structure 300 is removed. Then, the connection terminal 340 is formed on the connection pad 330 by turning the carrier substrate upside down.

Referring to FIG. 12F, a conductive pad 550 formed on the upper redistribution structure 500 and a conductive pad 610 located on the lower surface of the upper semiconductor package 600 are electrically connected to each other through a conductive bump 620. The upper semiconductor package 600 may be mounted on the upper surface of the upper redistribution structure 500.

The underfill layer 630 may be formed between the lower surface of the upper semiconductor package 600 and the upper surface of the upper redistribution structure 500 to surround the conductive bump 620. For example, the underfill layer 630 may be formed of a resin material formed by a capillary underfill method.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package comprising:
a lower redistribution structure;
an internal semiconductor chip on an upper surface of the lower redistribution structure;
an upper redistribution structure electrically connected to the lower redistribution structure through a conductive post; and
a molding layer between the upper redistribution structure and the lower redistribution structure, the molding layer surrounding the internal semiconductor chip,
wherein the upper redistribution structure comprises:
an insulating layer comprising a redistribution pattern and a first material configured to transmit light; and
a fiducial mark formed of the first material, and
wherein a lower surface of the fiducial mark is in contact with an upper surface of the molding layer.

2. The semiconductor package of claim 1, wherein the upper redistribution structure comprises a wiring region and a metal layer region electrically spaced apart from the wiring region, and
wherein the fiducial mark is in the metal layer region.

3. The semiconductor package of claim 2, wherein the fiducial mark is formed in a part of the metal layer region that does not comprise a metal layer.

4. The semiconductor package of claim 2, wherein the metal layer region comprises a dummy wire.

5. The semiconductor package of claim 2, wherein the fiducial mark is in contact with an outer edge of the wiring region.

6. The semiconductor package of claim 1, further comprising an upper semiconductor package on an upper surface of the upper redistribution structure.

7. The semiconductor package of claim 1, wherein two or more fiducial marks are provided.

8. The semiconductor package of claim 7, wherein the two or more fiducial marks have two different shapes.

9. The semiconductor package of claim 7, wherein N fiducial marks have N types of shapes, where N is a natural number greater than or equal to 2.

10. The semiconductor package of claim 7, wherein shapes of the two or more fiducial marks are same.

11. The semiconductor package of claim 10, wherein, based on two imaginary axes that pass through a center of a rectangular semiconductor package being orthogonal to each other and being positioned parallel to a width or length of the semiconductor package, at least one of the two or more fiducial marks is not symmetrical with the other of the two or more fiducial marks.

12. The semiconductor package of claim 10, wherein each of the two or more fiducial marks has a shape including an asymmetric protrusion angle formed by meeting edges forming a circumference of each of the two or more fiducial marks.

13. The semiconductor package of claim 12, wherein a direction of the protrusion angle of at least some of the two or more fiducial marks is formed in a direction different from a direction of the protrusion angle of the other of the two or more fiducial marks.

14. The semiconductor package of claim 1, wherein a shape of the fiducial mark is one of an ‘L’ shape, a square shape, a triangle shape, and a cross shape.

15. The semiconductor package of claim 1, wherein a shape of the upper redistribution structure is a rectangle, and
wherein a horizontal width and a vertical width of a shape of the fiducial mark are less than 1/10 of a horizontal width or a vertical width of the upper redistribution structure.

16. A semiconductor package comprising:
a lower redistribution structure;
an internal semiconductor chip on an upper surface of the lower redistribution structure;
an upper redistribution structure electrically connected to the lower redistribution structure through a conductive post; and
a molding layer between the upper redistribution structure and the lower redistribution structure, the molding layer surrounding the internal semiconductor chip,
wherein the upper redistribution structure comprises:
an insulating layer comprising a redistribution pattern and a first material configured to transmit light; and
a fiducial mark formed of the first material,
wherein a lower surface of the fiducial mark is in contact with an upper surface of the molding layer,
wherein the upper redistribution structure comprises a wiring region and a metal layer region electrically spaced apart from the wiring region, and
wherein the fiducial mark is in the metal layer region.

17. The semiconductor package of claim 16, wherein the fiducial mark has a shape with an asymmetric protrusion angle formed by meeting edges forming a circumference of the fiducial mark.

18. The semiconductor package of claim 17, further comprising an upper package on an upper surface of the upper redistribution structure.

19. A semiconductor package comprising:
a lower redistribution structure;
an internal semiconductor chip on an upper surface of the lower redistribution structure;
an upper redistribution structure electrically connected to the lower redistribution structure through a conductive post;
a molding layer between the upper redistribution structure and the lower redistribution structure, the molding layer surrounding the internal semiconductor chip; and
an upper semiconductor package on an upper surface of the upper redistribution structure,
wherein the upper redistribution structure comprises:
an insulating layer comprising a redistribution pattern and a first material configured to transmit light; and
a fiducial mark formed of the first material,
wherein a lower surface of the fiducial mark is in contact with an upper surface of the molding layer,
wherein the upper redistribution structure comprises a wiring region and a metal layer region electrically spaced apart from the wiring region, and
wherein the fiducial mark is in a part of the metal layer region that does not include a metal layer.

20. The semiconductor package of claim 19, wherein N (N is a natural number of 2 or more and 4 or less) fiducial marks have 1 to N types of shapes, and the fiducial marks have one or more shapes of ‘L’ shape, square, triangle, and cross shape,
wherein horizontal and vertical widths of a shape of the fiducial mark are less than 1/10 of a horizontal or vertical width of the upper redistribution structure.
